(19) United States
(12) Patent Application Publication
(10) Pub. No.: US 2004/0255856 A1
(43) Pub. Date: Dec. 23, 2004

(54) Method and device for depositing a plurality of layers on a substrate

(76) Inventor: Markus Schumacher, Kerpen (DE)

Correspondence Address: ST. ONGE STEWARD JOHNSTON & REENS, LLC, 986 BEDFORD STREET, STAMFORD, CT, 06905-5619, US

(21) Appl. No.: 10/820,089

(22) Filed: Apr. 7, 2004

Related U.S. Application Data
(63) Continuation of application No. PCT/EP02/10051, filed on Sep. 7, 2002.

(30) Foreign Application Priority Data
Oct. 8, 2001 (DE) 101 50 776.3
Feb. 20, 2002 (DE) 102 06 984.0

(51) Int. Cl. C23C 16/00

(52) U.S. Cl. 118/715; 427/8; 427/248.1

(57) ABSTRACT

The invention relates to a method for depositing a plurality of layers on a substrate using gaseous starting materials, whereby the layers are deposited in one single process chamber in successive process steps. The gas phase composition and/or the substrate temperature is varied without the process chamber being opened in the interim, in such a way that layers of different quality can be deposited successively in one deposition chamber.

This application is a continuation of pending International Patent Application No. PCT/EP02/10051 filed Sep. 7, 2002 which designates the United States and claims priority of pending German Application Nos. 101 50 776.3 filed Oct. 8, 2001 and 102 06 984.0 filed Feb. 20, 2002.

### FIELD OF THE INVENTION

The invention relates to a process and an apparatus for depositing a multiplicity of layers on a substrate by means of gaseous starting materials.

An apparatus for depositing in particular silicon carbide or silicon-germanium carbide is described by WO 01/14619 A1.

WO 01/61071 describes an apparatus which can be used to apply OLEDs or similar layer structures to a substrate.

WO 01/57289 A1 relates to an apparatus for depositing one or more layers on a substrate, with the starting material used being liquid or solid substances which are introduced into the process chamber in gas form.

In the field of integrated MIM (metal-insulator-metal) structures in large scale integrated CMOS components, deposition processes which generally take place sequentially in different deposition systems (chambers) and are usually also based on different deposition methods (physical, such as PVD or chemical processes (MOD); in this context in particular chemical vapor deposition, CVD for short or alternatively MOCVD (metalorganic chemical vapor deposition)), are used for the layer deposition of electrodes and dielectrics (in this case in particular oxidic dielectrics).

In addition to the need for an extremely high degree of automation when conveying the substrates which are to be processed between the various process chambers, the complexity also gives rise to a significant drawback with regard to process stability, but also “cost of ownership” in maintaining the various deposition systems. Nowadays, long handling, cooling and heating times are normal during the conveying of the substrates which are to be coated between the individual process chambers, but these have a highly adverse effect on the minimum required wafer throughput in the large-series production of components. A focal point in terms of component technology is in particular also the problem whereby a chemical change, for example caused by impurities in the surfaces resulting from wafer handling (wafer transport between the deposition steps), has an adverse effect on the electrical properties of the component as a result of interfacial states between the deposition of the bottom electrode and dielectric or between the deposition of dielectric and top electrode (as is customary in particular in the fabrication of what is known as the gate stack for integrated MOS transistors).

The invention is based on the object of developing an apparatus and a process which reduces, avoids and eliminates the abovementioned drawbacks.

The object is achieved by the fact that the layer structure is deposited without having to change to different deposition systems or chambers.

The layers are deposited in a single process chamber in successive process steps by merely altering the gas phase composition and/or the substrate temperature.

The layer sequence comprises in particular at least one oxide layer, on which a metal layer or a metal layer to which an insulating layer and a metal layer has been applied. Furthermore, the process is distinguished by the fact that the process chamber is pumped out and/or purged with inert gas between the individual process steps. As a result, the pressure inside the process chamber is brought to a level which is significantly lower than the process pressure. The temperature of the walls of the process chamber can be controlled in various ways. If the gas phase is being changed, the process chamber can be purged with noble gases, Ar, He, H₂ or N₂. During this purging phase, the substrate holder on which the substrate is located and a gas inlet member disposed above the substrate holder can be brought to an optimum process temperature. It is also possible for the process chamber walls, through which the gas can escape, to be brought to the required temperature in this way. This avoids condensation of the starting materials which have been introduced in gas form into the gas phase and can also decompose there.

The temperature of the gas phase is individually controlled by the actively heated wall of the process chamber or by the wall of the process chamber which is heated by means of heat conduction, so that the required gas phase reactions between the starting materials or the decomposition of the starting materials is optimized. The gas inlet system may also be cooled in regions, so that preliminary decomposition or preliminary reactions are prevented.

The deposited layers serve different purposes. By way of example, the metallic layer serves as an electrode. Between these two electrodes there is an insulating layer, so that a capacitor is constructed from the metal-insulator-metal layer system. In a known way, contact is made with the metal layers in process steps which follow the coating step and in which, inter alia, the substrate is divided up. According to the invention, in a sequential CVD coating operation without any reverse reaction, substrates are alternately coated with conductive and insulating layers in a multiprocess chamber. The process chamber comprises a vacuum-tight chamber, a temperature-controlled substrate holder, a gas inlet member and a gas outlet member, to which a pump is connected. The temperature of the substrate holder, and also that of the cover of the process chamber lying opposite the substrate holder, can be controlled. This can be effected by means of an electrical resistance, by means of infrared radiation or by means of electromagnetic radio frequency. Required cooling can be performed by means of a liquid medium (H₂O or the like). It is also possible for the process chamber walls to be heated in this way. In one preferred configuration, the substrate holder can also be driven in rotation by means of a rotary drive. It is even possible for rotationally driven, substrate carrier plates, which orbit in planetary style about the center of the substrate holder, to be located on the substrate holder. Temperature measurement in the substrate holder can be performed by means of a thermocouple, the feed to which takes place through the rotary lead-through. It is preferable for the process chamber to have intermediate volumes in the region of the areas which define and delimit the geometry of the reaction chamber. In each of these intermediate volumes there is a gas. This gas may be the process gas. The pressure in the intermediate volumes, like the gas composition in the intermediate volumes, can be adjusted. This makes it possible to adjust the thermal conductivity of the intermediate volumes. This makes it possible to control the temperature of the process chamber walls. The walls of the intermediate volumes may be very thin, inert quartz-glass plates. However, there is also provision for plates of this type to be thermally coupled to the wall. The gases in the intermediate volumes may have different gas compositions, for example hydrogen and nitrogen. Water cooling is also provided for.

In a refinement of the invention, there is provision for the process gases to be introduced into the process chamber in pulsed manner. The process gases can be generated from liquid or solid starting substances. They may, for example, originate from evaporators, where they are brought into a gaseous state by temperature-control means. It is preferable for the transition from liquid starting materials into the gas phase to be effected by contact-free evaporation. The liquid containers in which the liquid starting materials are located may also have a carrier gas stream flowing through them.

In this case, the carrier gas stream becomes saturated with the gas of the starting material. To control the temperature, i.e. in particular to heat or cool, the process chamber walls and the process chamber cover, it is possible for the process chamber cover or process chamber walls to be thermally coupled, via a gas gap, to a heat sink or to a heat source. Parasitic memory effects between different deposition sequences (dielectrics, electrodes; also different dielectrics or electrodes) are avoided by the process chamber being pumped out to a pressure below the process pressure. However, the pressure should not drop below the basic pressure of the system.

Residual contamination from chemical substances resulting from prior process sequences are preferably monitored by measurement by means of a residual gas analyzer.

The layer thickness may be monitored in situ during the process using optical methods. In particular, there is provision for the layer thickness growth to be monitored by means of in situ ellipsometry.

To avoid the drawbacks outlined in the introduction, the invention proposes an apparatus and a process in which a complete MIM structure or at least part of this structure can be produced in a single apparatus and in a single process step. The conductive layers (electrodes) and insulating layers (dielectrics, oxidic dielectrics) are in this case produced in particular using what is known as the sequential heterowafer MOCVD process. In this case, the application of electrode/insulator layer system takes place in just a single process chamber, with the substrate which is to be coated remaining in this single process chamber throughout the entire process flow, without the need for it to be moved to other process chambers. To avoid parasitic memory effects between different process sequences, the process chamber is configured for minimum dead volumes. In this case, between the process sequences the impurity levels can be reduced to a minimum by pumping out the process chamber to a pressure which is lower than the process pressure (but is at least equal to the base pressure of the process chamber). The residual impurities are monitored by means of what is known as a RGA or residual gas analyzer. Nevertheless, a continuous flow of gas in a preferred direction is advantageous.

During the deposition of (oxidic) dielectrics and electrodes, it is customary to use metalorganic starting substances (precursors), which in the most general case differ in terms of their vapor pressure and also in terms of their decomposition behavior. These precursors are either evaporated directly using what are known as bubblers and then introduced into the process chamber or are introduced into one or more heated volume(s) (evaporators) via the solution of the precursors in a suitable solvent as a liquid/solid solution, evaporated and then introduced into the process chamber in order to react on the substrate which is to be coated. These precursors often have a very narrow process window between condensation and decomposition, which requires the temperature of all the delimiting walls to be accurately controlled. In order, however, to allow rapid matching of all the wall temperatures in the event of a change in process sequence, it is necessary for all the boundary surfaces which define the process chamber to have a low heat capacity, which in general can only be realized with difficulty. To avoid this problem, what are known as intermediate volumes are introduced, which can be adjusted in terms of their pressure and heat conduction and to which very thin, inert (e.g. quartz glass) walls facing the interior of the process chamber are coupled. Therefore, the temperature of the inner walls is controlled by heat transfer from the temperature-controlled process chamber outer wall, via an intermediate volume of adjustable heat conduction, to the inert, thin inner wall facing the interior of the process chamber. The heat conduction properties of the intermediate volumes are adjusted by means of a gas mixture by means of two gases which have different thermal conduction coefficients; furthermore, the pressure of this gas mixture can be adjusted freely. It is possible for the temperatures of different regions of the walls and of the gas inlet to be controlled differently.

### BRIEF DESCRIPTION OF DRAWINGS

Exemplary embodiments of the invention are explained below on the basis of appended drawings, in which:

FIG. 1 shows a first exemplary embodiment of a CVD installation for carrying out the process.

FIG. 2 shows a second exemplary embodiment of a CVD installation for carrying out the process.

### DETAILED DESCRIPTION OF DRAWINGS

The apparatus illustrated in the drawings has a process chamber 6 which is surrounded on all sides. The process chamber 6 has a feed line which leads to a gas inlet member 7. Either a process gas or a process gas mixed with a carrier gas can be introduced into the process chamber 6 through this feed line, or a purge gas can be introduced through the line 5.

The gas inlet member 7 comprises a flat-cylindrical hollow body, the base of which has a multiplicity of openings arranged in the style of a screen, out of which the gas can flow into the process chamber 6. In a position parallel to and at a distance from the gas inlet member 7, beneath it, there is a substrate holder 8 for holding a substrate. Below the substrate holder 8, which can also be rotated by means which are not shown in the drawings, there is a heater 12. This heater may be a RF heater or an IR heater.

It is not only the substrate holder 8 which can be heated to a temperature at which the process gas is decomposed. The walls of the process chamber housing 11 may also have heaters 13 for heating the walls. The wall temperature is in this case lower than the temperature of the substrate holder 8.

Beneath the substrate holder 8 there is a gas discharge line. The unused gas is pumped out of the process chamber 6 through this discharge line by a pump 10.

In the gas discharge line there is a residual gas analyzer 9 which analyzes the composition of the gas which has been pumped out of the process chamber 6 by mass spectrometry.

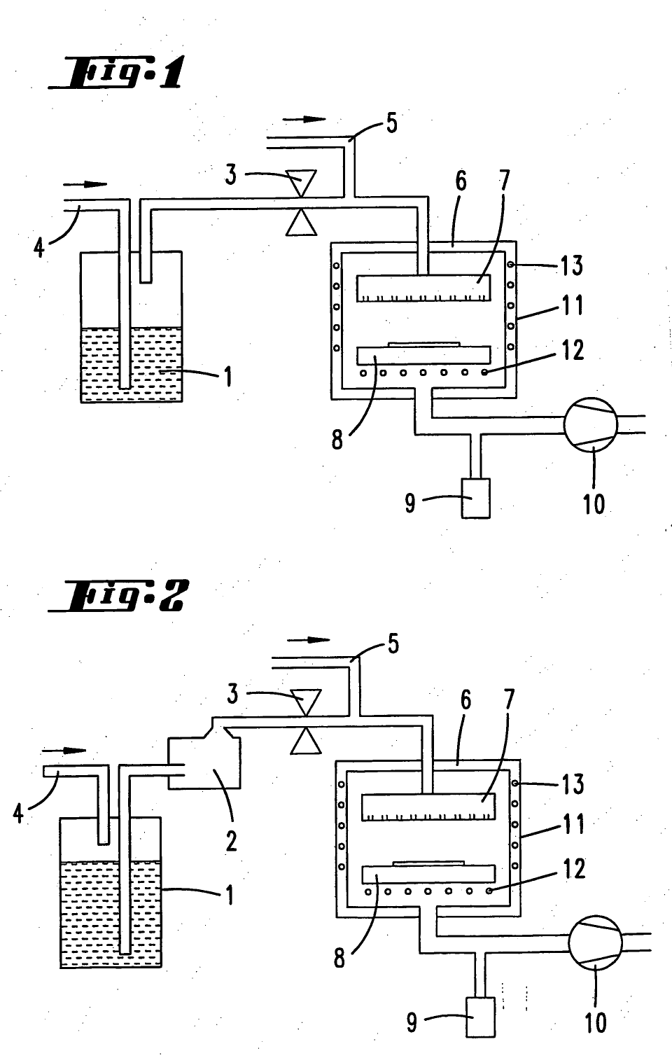

The two exemplary embodiments illustrated in the drawings differ substantially by virtue of the configuration of the sources. In the drawings, only a single source is illustrated, for the sake of clarity. However, a plurality of, in particular three, sources may be required for the deposition of metal-insulator-metal layers. A first source for providing a metal organic compound, for example a metalorganic platinum compound for deposition of the first metallization layer, a second source, which contains a barium-strontium-titanium oxide, known as a perovskite, for deposition of a dielectric, and a third source, which contains, for example, a metalorganic ruthenium compound, for deposition of the second metallization layer. The metalorganic compounds, like the BST compound, may be dissolved in a solvent. In this case, they are in a tank 1, into which carrier gas is introduced through a feed line 4. In the exemplary embodiment illustrated in FIG. 1, the tank functions as a scrubbing vessel. In the exemplary embodiment illustrated in FIG. 2, the liquid in the tank is forced into an evaporator 2 through a riser. In both cases, the BST compound or the metal organic compound which has been converted into a gas form is fed to the gas inlet member 7 via a pipeline which can be closed off by means of a valve 3.

The process is carried out as follows:

In a first process step, a metal layer is deposited on the substrate resting on the substrate holder 8 as a result of a metal organic starting material which contains platinum and is dissolved in a solvent being converted into a gas form. The substrate preferably consists of silicon. The starting material, together with the solvent, is fed to the showerhead-like gas inlet member 7 and is passed into the process chamber 6 through the openings in the gas inlet member 7. Suitable gas phase transport (convection and diffusion) causes the gas to reach the hot substrate holder 8, where a decomposition reaction takes place on the surface. A platinum layer is formed on the substrate as a reaction product. As soon as the required layer thickness has been deposited, the valve 3 is closed and an inert gas is introduced into the process chamber through the line 5. While the process chamber 6 is being purged with the inert gas, the pump 10 can lower the internal pressure in the process chamber 6 a number of times, so that increased gas exchange takes place. The residual gas content is measured by spectrometry by means of the residual gas analyzer 9. The concentration of the solvent and the concentration of the metalorganic compound are measured. When the concentration of residual gas measured drops below a limit, the purging operation is concluded.

The purging operation is followed by a second process step, in which a barium-strontium-titanium-oxygen compound, known as a perovskite, is introduced into the process chamber 6 through the gas inlet member 7 instead of the metalorganic platinum compound. It is important that the process chamber 6 be substantially free of solvent prior to the introduction of this gas which is broken down to form a dielectric, since the BST compound reacts very sensitively to the solvent in the gas phase.

The stoichiometry of the barium-strontium-titanium oxide can be set by the use of a suitable temperature and/or by the use of suitable other process parameters. This makes it possible to influence the dielectric constant of the dielectric layer.

However, as an alternative to a dielectric material, it is also possible to deposit a ferroelectric material. In this case too, when the required layer thickness, which can be measured in situ during the growth, is reached, the incoming flow of gas is closed off by closing a valve. Then, as described above, the process chamber 6 is purged; in this case too, the power of the pump can be briefly increased in order to lower the total pressure inside the process chamber 6.

In this case too, the residual gas content is analyzed by spectrometry by means of the residual gas analyzer 9. In this case, the oxygen concentration in the gas phase is monitored. When this concentration drops below a limit, the purging operation is terminated. The second process step is followed by a third process step, which is carried out substantially in the same way as the first process step, except that a ruthenium-containing metalorganic compound is selected instead of a platinum-containing metalorganic compound. Purging of the process chamber 6 may also follow the third process step.

All features disclosed are (inherently) pertinent to the invention. The disclosure content of the associated/appended priority documents (copy of the prior application) is hereby incorporated in its entirety in the disclosure of the application, partly with a view to incorporating features of these documents in claims of the present application.

What is claimed is:

1. Process for depositing a multiplicity of layers on a substrate by means of gaseous starting materials, the layer sequence comprising at least one oxide layer and a metal layer deposited thereon, and the layers being deposited in a single process chamber in successive process steps by simply altering the gas phase composition in the process chamber and/or the substrate temperature, characterized in that between the individual process steps the process chamber is pumped out and purged with inert gas, the exhaust-gas which is pumped out of the process chamber (6) being analyzed for residual constituents of the starting material and/or for solvent, and the purging operation being terminated only when this residual gas concentration and/or the solvent concentration drops below a minimum value.

2. Apparatus for depositing a multiplicity of layers on a substrate by means of gaseous starting materials, the layer sequence comprising at least one oxide layer and a metal layer deposited thereon, having a process chamber for depositing the layers in successive process steps, it being possible, between the process steps for layer deposition, to alter the gas phase composition in the process chamber and/or the substrate temperature, characterized by a pump (10) for pumping out the process chamber between the individual process steps and a device for purging the process chamber with inert gas in a purging operation between the process steps, and a residual gas analyzer for analyzing the exhaust-gas pumped out of the process chamber (6) for residual constituents of the starting material and/or for solvent and for interrupting the purging operation when the residual gas concentration drops below a minimum value.

3. Process or apparatus according to one or more of the preceding claims or in particular according thereto, characterized in that the walls of the process chamber are or can be controlled to different temperatures.

4. Process according to one of the preceding claims, characterized in that in the first process step a metalorganic starting material, which may optionally have been dissolved in a solvent, is converted into the gas phase and is introduced into the process chamber (6), if appropriate together with the solvent, by means of a showerhead-like gas inlet member (7), and the gas inlet member (7) and the process chamber (6) are purged with inert gas (5) after the supply of this starting material has been switched off.

5. Process according to claim 4, characterized in that in the second. process step a dielectric layer is deposited on the metal layer, as a result of a perovskite, which has optionally been dissolved in a solvent, as starting material being converted into the gas phase and being introduced into the process chamber (6), if appropriate together with the solvent, by means of the showerhead-like gas inlet member (7), and the gas inlet member (7) and the process chamber (6) being purged with an inert gas (5) after the supply of this starting material has been switched off, the exhaust-gas which has been pumped out of the process chamber (6) being analyzed, in particular by mass spectrometry, for residual constituents of the starting material, and the purging operation being terminated only when the residual gas concentration, in particular the oxygen concentration, drops below a minimum value.

6. The process as claimed in claim 5, characterized in that in a third process step a metal layer is deposited on a dielectric layer which has previously been deposited, a metalorganic starting material, which has optionally been dissolved in a solvent, being converted into the gas form and being introduced into the process chamber (6), if appropriate together with the solvent, by means of the showerhead-like gas inlet member (7), and the gas inlet member (7) and the process chamber (6) being purged with an inert gas (5) after the supply of this starting material has been switched off, the exhaust-gas which is pumped out of the process chamber (6) being analyzed, in particular by mass spectrometry, for residual constituents of the starting material and/or the solvent, and the purging operation being terminated only when the residual gas concentration drops below a minimum value.

7. Process according to one or more of the preceding claims or in particular according thereto, characterized in that the purging of the process chamber (6) with the inert gas (5) is associated with one or more pressure changes.

8. Process according to one or more of the preceding claims or in particular according thereto, characterized in that the first metal layer is a platinum layer.

9. Process according to one or more of the preceding claims or in particular according thereto, characterized in that the dielectric layer consists of a barium-strontium-titanium-oxygen compound.

10. Process according to one or more of the preceding claims or in particular according thereto, characterized in that the second metal layer is a ruthenium layer.
